(19) United States
(12) Patent Application Publication
(10) Pub. No.: US 2024/0330557 A1
(43) Pub. Date: Oct. 3, 2024

(54) TWO BY TWO LOGIC CHIPLET

(71) Applicant: XILINX, INC., San Jose, CA (US)

(72) Inventors: Martin L. VOOGEL, Niwot, CO (US); Matthew H. KLEIN, Redwood City, CA (US)

(21) Appl. No.: 18/128,368

(22) Filed: Mar. 30, 2023

(51) Int. Cl. G06F 30/392; G06F 30/398

(52) U.S. Cl. CPC G06F 30/392; G06F 30/398

(57) ABSTRACT

Embodiments herein describe various 2×2 configuration of integrated circuits (ICs), where the ICs can communicate with multiple neighboring ICs using chip-to-chip interfaces. As such, 2×2 configurations are improvements over other horizontal chip integration formats (such as 1×2, 1×3, and 1×4) where some of the ICs can directly communicate with only one other IC.

### TECHNICAL FIELD

Examples of the present disclosure generally relate to arranging integrated circuits in a two by two (2×2) configuration.

### BACKGROUND

Many devices include multiple integrated circuits (or dies or chips) that are interconnected on a substrate or interposer. That is, chip-to-chip connections can be used to form devices that are 1×2, 1×3, 1×4, etc. However, in a 1×2 configuration, the two integrated circuits (ICs) communicate using only one side, which limits the number of chip-to-chip signals. With a 1×3 configuration, only the middle chip uses multiple sides to communicate with other chips. Similarly, in a 1×4 configuration, only two of the four ICs can use multiple sides to communicate with other chips.

### SUMMARY

One embodiment described herein is a device that includes an interposer with a horizontal stitch and a vertical stitch formed from overlapping exposure areas and four integrated circuits (ICs) disposed on the interposer in a 2×2 configuration where each of the four ICs is connected via the interposer to neighboring ICs on two sides.

One embodiment described herein is a method that includes forming an interposer with a horizontal stitch and a vertical stitch using overlapping exposure areas and disposing four ICs on the interposer in a 2×2 configuration where each of the four ICs is connected via the interposer to neighboring ICs on two sides.

One embodiment described herein is a device that includes four integrated circuits (ICs) arranged in a 2×2 configuration where each of the four ICs is connected to neighboring ICs on at least two sides and where the four ICs have the same design.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a 2×2 configuration of ICs on an interposer, according to an example.

FIG. 2 is a flowchart for forming an interposer with horizontal and vertical stitches to support a 2×2 configuration of ICs, according to an example.

FIG. 3 illustrates an interposer with horizontal and vertical stitches, according to an example.

FIG. 4 illustrates a 2×2 configuration of ICs using mirrored ICs, according to an example.

FIG. 5 illustrates a 2×2 configuration of ICs using a rotated IC, according to an example.

FIG. 6 illustrates using a rotated IC to improve yield, according to an example.

FIG. 7 illustrates using a rotated IC to improve yield, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe various 2×2 configuration of ICs, where the ICs can communicate with multiple neighboring ICs using chip-to-chip interfaces. As such, 2×2 configurations are improvements over other horizontal chip integration formats (such as 1×2, 1×3, and 1×4) where some of the ICs can directly communicate with only one other IC.

In one embodiment, the ICs forming the 2×2 configuration are disposed on an interposer with a horizontal stitch and a vertical stitch. Using stitches enables the interposer to be larger than a reticle size so that multiple dies (which are also constrained by the reticle size) can be disposed on a same interposer. To form the vertical and horizontal stitches, four exposure areas (which are at or below the reticle size and slightly overlap) can be used to fabricate the interposer. The ICs can then be disposed on the four corners of the interposer and then interconnected using traces in the interposer.

While the ICs in the 2×2 configuration can be different, in one embodiment two of the ICs are a same design (e.g., exactly the same) while the other two ICs are a mirror of that design. Doing so lines up the interfaces of the ICs so that straight connections can be formed in the interconnect when the ICs are arranged in the 2×2 configuration.

In another embodiment, the same IC can be used to form a 2×2 configuration, but the IC is rotatable so that straight connections can be formed in the interconnect when connecting neighboring chips. Using straight connections simplifies the routing in the interconnect and permits many more chip-to-chip connections relative to an interposer that supports connections that cross in the interposer.

In yet another embodiment, rotatable ICs can be used to improve yield. Often an IC fabrication process can introduce a defect in an IC. Rather than simply discarding any IC with a defect, the defective ICs can be used to form a device that is sold with less capability or performance than a device containing only fully function ICs. Using a rotatable IC means that ICs with defects can be rotated when being placed in the device so that the defective areas of the IC are placed in portions of the device that are unused, thereby increasing yield.

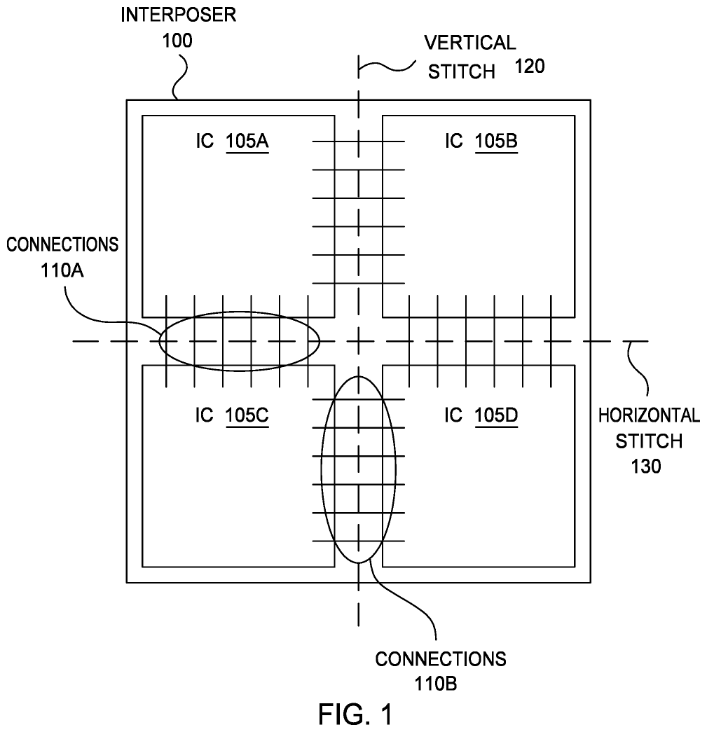

FIG. 1 illustrates a 2×2 configuration of ICs 105 on an interposer 100, according to an example. In this top view, the ICs 105 are disposed in respective corners of the interposer 100. The interposer 100 provides connections between neighboring ICs 105. For example, the interposer 100 can be a silicon interposer that includes one or more layers that include traces for forming the connections 110. In one embodiment, the ICs 105 may be mounted onto the interposer using, e.g., copper pillars, which then electrically couple the ICs 105 to the connections 110 that route electrical signals from one IC 105 to a neighboring IC 105.

Unlike 1×2, 1×3, or 1×4 arrangements where at least some of the ICs only use one side to communicate with a neighboring IC, in the 2×2 configuration shown in FIG. 1, each IC 105 uses two sides to communicate with the two neighboring ICs. For example, IC 105C uses the horizontal connections 110B to communicate with IC 105D and the vertical connections 110A to communicate with the IC 105A. Thus, the 2×2 configuration effectively doubles the amount of chip-to-chip connections that each IC can be have relative to some of the ICs in the 1×2, 1×3, or 1×4 arrangements which communicate using only one side.

In this embodiment, the interposer 100 has a surface area that exceeds a reticle limit of the fabrication techniques used to fabricate the interposer. The size of an IC 105 is limited by the reticle limit which defines the amount of area that can be exposed and processed using masks. Currently, for a monolithic die, the maximum size is limited to 33-26 mm which is the reticle limit. Thus, the widths and heights of the ICs 105 are limited to this reticle limit.

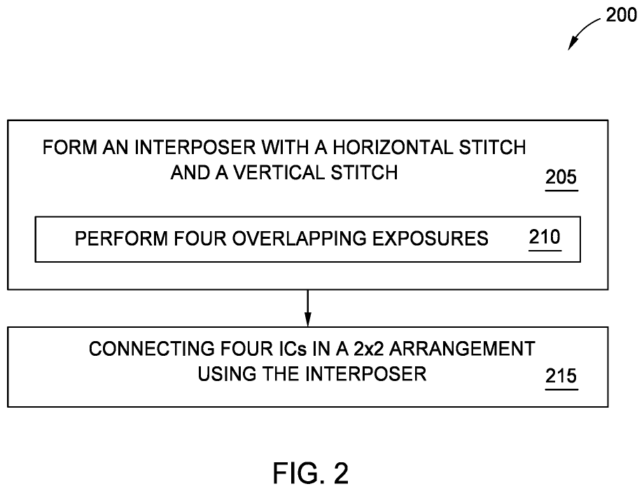

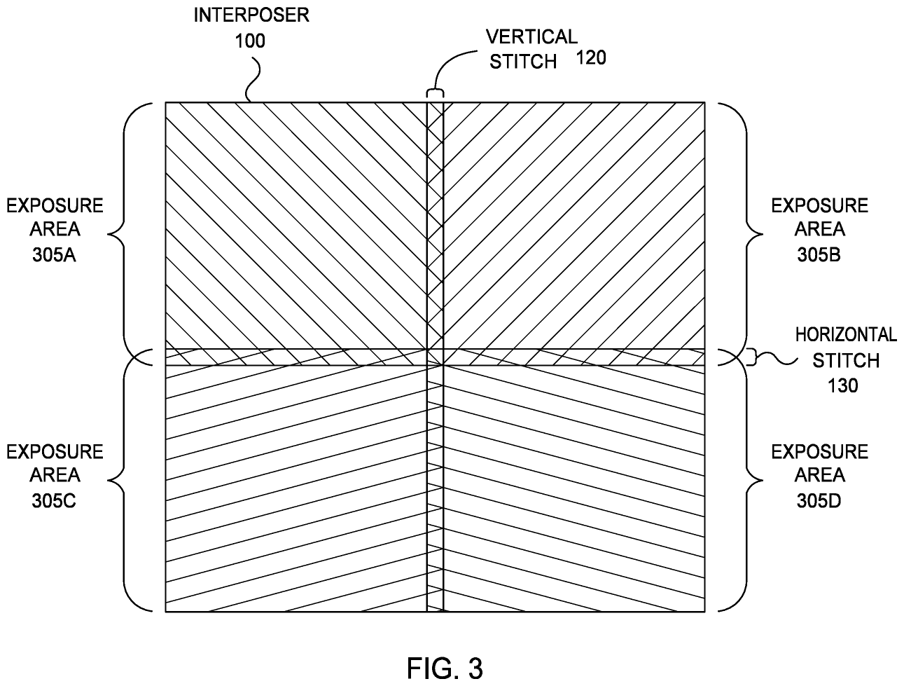

In order for the interposer 100 to support multiple ICs 105 which have sizes that are at or just below the reticle limit, it has to have a surface area that exceeds the reticle limit. This means that interposer 100 cannot be fabricated using a single exposure process. Instead, the interposer 100 includes a vertical stitch 120 and a horizontal stitch 130 where multiple exposure areas slightly overlap. This permits the interposer to still have traces to form the connections 110 and have sufficient surface area to support the 2×2 configuration of the ICs 105. Fabricating the interposer 100 is discussed in more detail in FIGS. 2 and 3.

In one embodiment, the interposer 100 has a total surface area that is three times the size of the reticle limit (e.g., the maximum reticle field). Moreover, unlike interposers that support 1×2, 1×3, and 1×4 configurations that may only have horizontal stitches, the interposer 100 has both a horizontal stitch 130 and a vertical stitch 120.

FIG. 2 is a flowchart of a method 200 of fabricating an interposer with horizontal and vertical stitches to support a 2×2 configuration of ICs, according to an example. At block 205, the method 200 forms an interposer with a horizontal stitch and a vertical stitch. In one embodiment, at block 210, these stitches are formed by performing four overlapping exposures.

FIG. 3 illustrates the interposer 100 with horizontal and vertical stitches 120, 130 formed using four exposure areas 305A-D. In this example, each exposure area 305 has a size that is at or below the reticle limit (e.g., the maximum reticle field). Thus, each of the exposure areas 305 can be made using a separate set of masks.

As shown, the exposure area 305A overlaps to the right with the exposure area 305B and at the bottom with the exposure area 305C. The exposure area 305A also slightly overlaps with the exposure area 305D at the middle of the interposer 100 (where all four of the exposure areas 305 slightly overlap). In addition to overlapping with the exposure area 305A, the exposure area 305B overlaps at the bottom with the exposure area 305D. Moreover, the exposure area 305D overlaps at the left with the exposure area 305C.

By ensuring the exposure areas 305 slightly overlaps, this provides the ability to form the vertical stitch 120 and the horizontal stitch 130 in these overlapping portions. Without overlapping the exposure areas 305 (e.g. if the exposure areas touched, but did not overlap), it would be very difficult to pattern the traces into the interposer 100 to from the chip-to-chip connections shown in FIG. 1. This is because of misalignment between two exposures. In one embodiment, the overlap of exposures and the minimum widths and space of features (metal lines) on interposer 100 near the stitch zones is greater than the maximum misalignment. Without overlapping the exposure areas 305, it would be difficult to pattern traces that extend between the exposure areas 305 in order to form the chip-to-chip connections 110 illustrated in FIG. 1.

While masks sets are expensive, masks for the interposer 100, which are currently formed using a 65 nm fabrication method, are much cheaper than masks sets for the ICs, which are currently formed using 7 nm or 3 nm fabrications methods. As such, it is relatively inexpensive to form an interposer that exceeds the reticle limit. In contrast, it may be impossible to use overlapping exposure areas to form an IC that exceeds the reticle limit using a 7 nm or 3 nm technology.

Returning to the method 200, at block 215, four ICs are connected in a 2×2 configuration using the interposer. For example, the interposer may include bond pads to which the ICs are solder bonded to the interposer. Doing so electrically connects the ICs to chip-to-chip connections that extend between neighboring ICs as shown in FIG. 1.

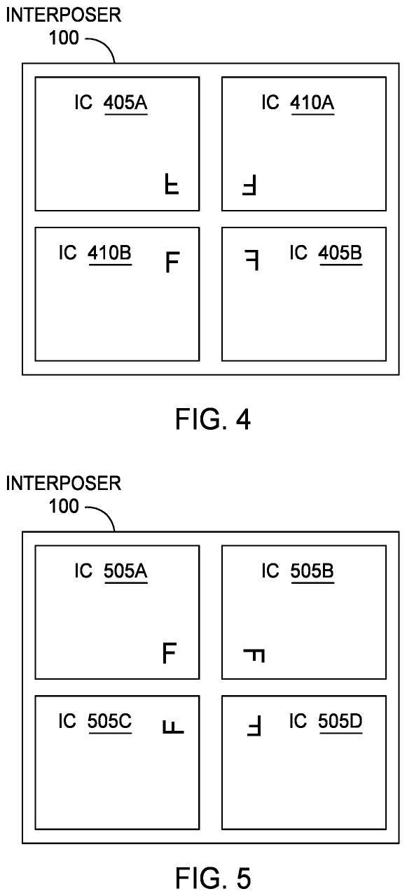

FIG. 4 illustrates a 2×2 configuration of ICs using mirrored ICs, according to an example. Although not labeled, the interposer 100 in FIG. 4 can include the vertical and horizontal stitches discussed in the embodiments above. That is, the interposer 100 may exceed a maximum reticle field. However, this is not a requirement. For example, the interposer 100 may have dimensions that are within the maximum reticle field, but the ICs on the interposer 100 may be much smaller than the maximum reticle field so they can fit on the interposer 100.

FIG. 4 illustrates disposing two pairs of ICs on the interposer in the 2×2 configuration. Each pair of ICs may be exactly the same (e.g., formed using the same mask set). In this embodiment, the ICs 405A and 405B are the same IC while the ICs 410A and 410B are the same IC. The “F” character indicates the rotation of the ICs relative to each other. In this example, the IC 405A is the same as the IC 405B but has been rotated 180 degrees when disposed on the interposer 100. Doing so can align IO and transceivers on the ICs 405 to each other. As a result, the chip-to-chip connections between the IC 405A and 405B can be straight which, as discussed above, can greatly increase the number of chip-to-chip connections that can extend through the interposer 100. The same is true of the ICs 410 where the IC 410A is the same as the IC 410B but has been rotated 180 degrees when placed on the interposer 100.

In addition, the ICs 410A and 410B are mirror designs of the ICs 405A and 4058. For example, after designing the ICs 405A and 405B, a chip designer can instruct the software design application to mirror the design. This is illustrated by the “F” characters on the ICs 405A and 405B being mirror images of the “F” characters on the ICs 410A and 410B. By mirroring the ICs, the IO and transceivers between the IC 405A and the IC 410A, and between the IC 405B and the IC 410B align so that the horizontal chip-to-chip connections can extend straight through the interposer 100 (i.e., not cross) like the vertical chip-to-chip connections. Thus, the device in FIG. 4 illustrates two pairs of ICs that have essentially the same performance and the same functions, where one pair is a mirrored version of the other pair.

While using two pairs of mirrored ICs enables the straight chip-to-chip connections through the interposer 100, it also means that two mask sets are used. That is, the ICs 405A and 405B are fabricated using a different mask set than the ICs 410A and 410B, which increases cost. However, FIG. 5 avoids the cost of an additional mask set.

FIG. 5 illustrates a 2×2 configuration of ICs using a rotated IC, according to an example. Like in FIG. 4, FIG. 5 illustrates mounting four ICs 505A-D on the interposer 100 (which may, or may not, exceed the maximum reticle field). However, unlike in FIG. 4, the four ICs 505 are the same design (e.g., formed using the same mask set). Thus, the ICs 505 have the same performance and function as each other.

Again, the “F” character is used to illustrate the relative rotation of the ICs 505. In this example, the IC 505B is rotated 90 degrees relative to the IC 505A, the IC 505C is rotated 90 degrees relative to the IC 505B (and 180 degrees relative to the IC 505A), and the IC 505D is rotated 90 degrees relative to the IC 505C (and 270 degrees relative to the IC 505A).

While the 2×2 configuration in FIG. 5 illustrates using the same IC design (and thus, only one mask set is needed), it is also much more difficult to design the ICs 505 so that the IO and transceivers on the sides align when rotated as shown. Put differently, it is much more difficult to have straight, non-crossing chip-to-chip connections through the interposer 100 for the ICs 505. For example, the circuits in the rotated ICs 505 may not be perfectly aligned horizontally and vertically between neighboring ICs 505, complicating the interposer routing to connect the ICs 505. Moreover, the ICs 505 may have to be perfectly square in order to align when rotated as shown, while in FIG. 4, the dies could be rectangular with two of the sides being longer than the other, perpendicular sides and still have their IO circuitry align.

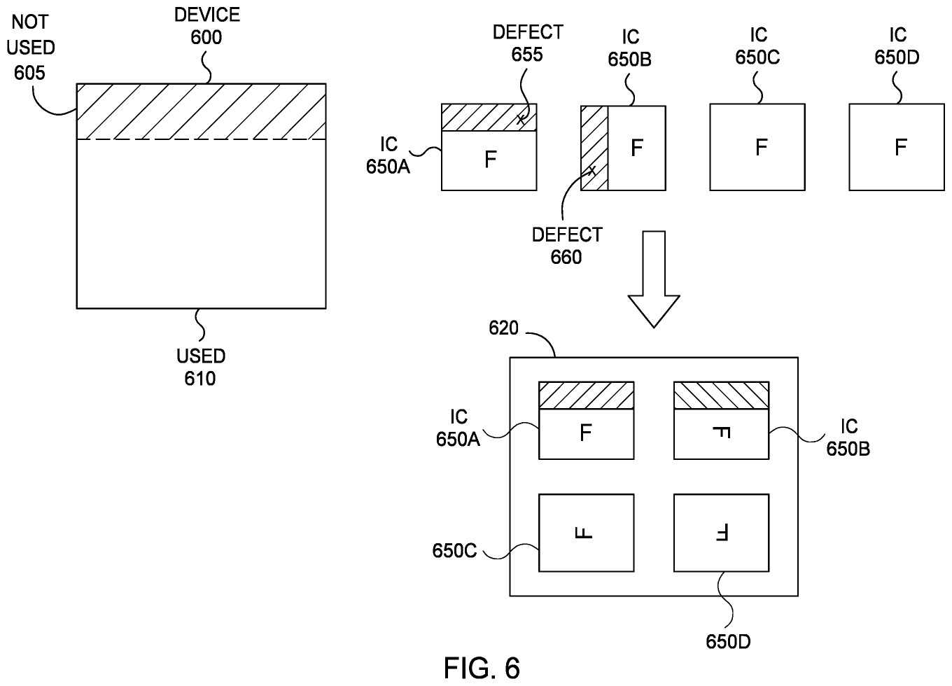

FIG. 6 illustrates using a rotated IC to improve yield, according to an example. FIG. 6 explains a scenario where the rotated IC 2×2 configuration in FIG. 5 can be used to improve yield. Despite tremendous improvements in IC fabrication, defects can still arise in an IC. This can result in the IC having to be discarded for having only one defect.

However, to improve yield, manufacturers can sell devices that are advertised as having lower performance than a fully functional device. As an example, if the device illustrated in FIG. 5 has four fully functional ICs 505 (e.g., none of the ICs 505 have a defect), then the device is sold as a fully functional device. In contrast, FIG. 6 illustrates a device 600 that is defined as having only 75% of the resources (or 75% of the performance) of the fully functional device. That is, the product definition of the device 600 can indicate that 25% of the device 600 includes not used circuitry 605 while the remaining 75% of the device 600 is used circuitry 610. Specifically, the not used circuitry 605 includes at least one defect while the used circuitry 610 is defect free.

FIG. 6 also illustrates four ICs 650 that have the same design, but two of the ICs have defects. For example, after fabricating the ICs 650, a testing process can be used to identify that the IC 650A has a defect 655 and the IC 650B has a defect 660 while the ICs 650C and 650D are defect free. However, rather than discarding the ICs 650A and 650B, they can still be used in a device 670 that satisfies the product definition of the device 600 (i.e., 75% of the circuitry is usable).

As shown, there is a defect (or multiple defects) in one half of the IC 650A and the IC 650B. In reality, the defect may affect a very small portion of the ICs 650A and 650B, but in order to satisfy the product definition of the device 600, only one half of the circuitry in the ICs 650A and 650B have to be usable. The hashing illustrates the halves of the ICs 650A and 650B that will not be used due to having a defect.

Because the ICs 650 are rotatable, the ICs 650A and 650B can be used to form the device 670. That is, according to the product definition of the device 600, the top 25% of the circuitry should not be used. Thus, because the defect 655 is in the top half of the IC 650A, this half of the IC 650A can be deactivated and then placed in the device 670 in the upper right corner. In contrast, the defect 660 is in the bottom left of the IC 650B, so that the left half of this IC is deactivated. Thus, when the IC 650B is rotated when placed in the device 670, the deactivated half is now in the top half of the device 670. Because the ICs 650 are rotatable, they can be rotated and still be connected to neighboring ICs. As such, the ICs 650A and 650B satisfy the product definition where the top 25% of the circuitry is not used, while the remaining 75% of the circuitry is used (which includes the usable halves of the ICs 650A and 650B and all of the circuitry in the ICs 650C and 650D).

Advantageously, having rotatable ICs 650 mean that the defects can be located in various locations of the ICs and still could be used in a product with reduced performance, such as the device 600. In this example, if a defect is in the upper half or the lower left corner of the ICs 650, the IC could still be used in the device 670. As such, the ICs 650 can have a defect in 75% of their area and still be used in the device 670. However, if the defect is in the lower right corner, then it could not be used since it could not be rotated to satisfy the product definition of the device 600. Those ICs may be discarded, or may be usable in a device with a different product definition. In any case, using a rotatable die can improve the yield by providing more opportunities to use ICs with defects in lower-performing devices compared to a device where rotatable dies are not used in a 2×2 configuration.

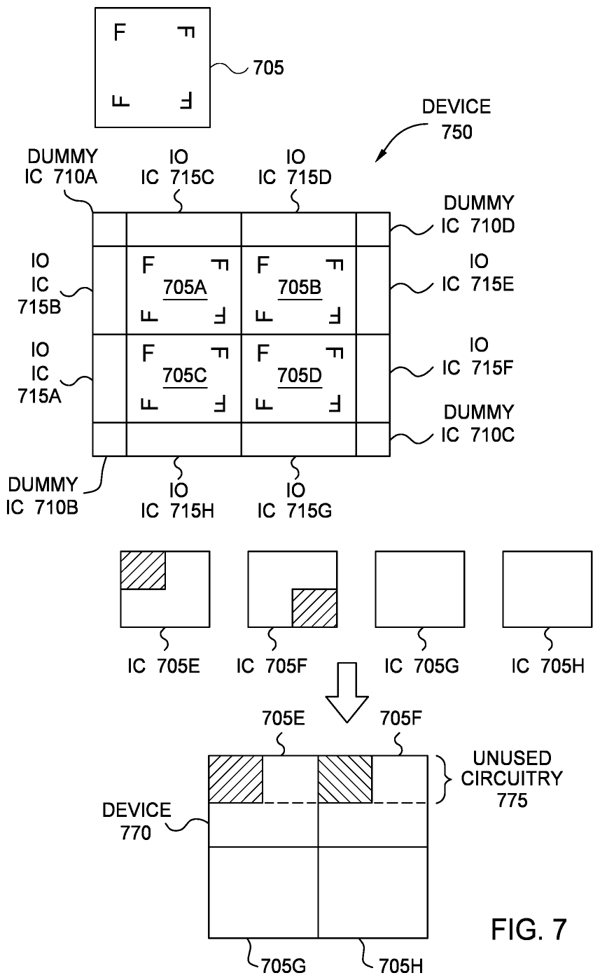

FIG. 7 illustrates using a rotatable IC to improve yield, according to an example. Like in FIG. 6, FIG. 7 illustrates a scenario where the rotated IC 2×2 configuration in FIG. 5 can be used to improve yield when ICs have defects. For ease of explanation, the embodiments in FIG. 7 are discussed in the context of the device 600 in FIG. 6 that is defined as having only 75% of the resources (or 75% of the performance) of the fully functional device. That is, the product definition of the device 600 can indicate that 25% of the device 600 includes not used circuitry 605 while the remaining 75% of the device 600 is used circuitry 610.

In FIG. 6, each IC 650 could be rotated and used in the 2×2 configuration. In FIG. 7, each IC 705 is also the same, but each of the ICs 705 has complete, logical rotational symmetry where there are four orientation allowed for each IC-0, 90 degrees, 180 degrees, or 270 degrees. That is, while the device 670 in FIG. 6 had a product level rotation symmetry axis, a device 750 in FIG. 7 has both a product level rotation symmetry axis and a die level rotation symmetry axis.

The device 750 can include an interposer on which dummy ICs 710A-D, IO ICs 715A-H, and the IC 705A-D are disposed. The dummy ICs 710 are optional and may be used for mechanical integrity reasons. The IO ICs 715 can include IO circuitry and transceivers that are coupled to circuitry in the ICs 705. The interposer can provide direct chip-to-chip connections between the IO ICs 715 and the ICs 705.

In one embodiment, the ICs 705 contain programmable logic (e.g., programmable fabric) with direct connections that couple the programmable logic (or programmable fabric) to the chip-to-chip connections extending through the interposer and to the IO ICs 715. Although not shown, the IO ICs 715 can also be connected via the interposer to external connections that permit external devices to communicate with the ICs 705 via the IO ICs 715.

The “F” characters for the ICs 705A-D indicate that their rotation does not matter. That is, the ICs 705A-D are designed so that they can be placed in any location of the device 750, with any orientation. This is unlike in the device 670 in FIG. 6 where each location on the device 670 corresponds to a particular orientation of the ICs 650.

To meet the product definition of the device 600, the top 25% of the circuitry of the device 750 may be unused, which gives the manufacturer the opportunity to sell a device that includes ICs 705 with defects. FIG. 7 illustrates four ICs 705E-H where two of the ICs (i.e., IC 705E and 705F) have respective defects and the other two ICs (i.e., 705G and 705H) do not have defects.

FIG. 7 illustrates forming a device 770 from the ICs 705E-H. In this example, the IC 705E is placed in the upper left of the device 770. The IC 705F is placed in the upper right corner of the device 770 and is rotated 180 degrees relative to its orientation shown above in FIG. 7. However, due to the ICs having rotational symmetry, the orientation of the ICs 705 does not affect their function. That being said, because the ICs 705E and 705F have defects, the defective areas of these ICs are rotated into the part of the device 770 that includes unused circuitry 775. This could be accomplished by rotating the IC 705F 180 degrees as shown, or by rotating the IC 705F 90 degrees (counter clockwise). In either case, the portion of the IC 705F with the defect is part of the unused circuitry 775 of the device.

Thus, like in FIG. 6, half of the ICs 705E and 705F are not used in the device 770. By having rotational symmetry, the ICs 705 can have a defect in 100% of their area and still be used in the device 770. That is, the ICs 650 in FIG. 6 could recover from a defect in 75% of the area, but the ICs 705 can recover from a defect in any area (e.g., the upper left and right corners and the lower left and right corners). Thus, if the ICs 705 has a defect anywhere, they can still be used to satisfy the product definition corresponding to the device 770. That is, these defective ICs could be used in the two upper locations of the device 770.

If an IC 705 had multiple defects, it still might be usable in the device 770. For instance, if there were two defects in the same quarter of the die (e.g., multiple defects in the upper left region), then the IC 705 could be used as shown in FIG. 7. Further, if there were multiple defects in two contiguous regions (e.g., defects in both the upper left and upper right corners, or in the upper left and lower left corners), then the IC could still be rotated such that the defective areas are within the unused circuitry 775. However, if there were defects in three regions (e.g., three corners) of an IC 705, or defects in non-contiguous regions in the IC 705 (e.g., defects in both the upper left and the lower right corners), then those ICs could not be used in the device 770. In any case, by using ICs 705 with rotational symmetry, the yield of those ICs 705 can be improved even further relative to the device in FIG. 6.

Further, the redundancy and yield improvement techniques discussed in FIGS. 6 and 7 are not limited to using an interposer as described in FIGS. 1-5 with a vertical stitch and a horizontal stitch. For example, the devices in FIGS. 6 and 7 may include an interposer with no stitches. Or the ICs in the devices may be connected without using any interposer, e.g., using the substrates of the ICs to enable chip-to-chip connections.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A device, comprising:
an interposer with a horizontal stitch and a vertical stitch formed from overlapping exposure areas; and
four integrated circuits (ICs) disposed on the interposer in a 2×2 configuration, wherein each of the four ICs is connected via the interposer to neighboring ICs on two sides.

2. The device of claim 1, wherein a total surface area of the interposer is greater than a maximum reticle field corresponding to the exposure areas.

3. The device of claim 2, wherein the total surface area of the interposer is at least three times a size of the maximum reticle field.

4. The device of claim 2, wherein the horizontal stitch and the vertical stitch are formed by slightly overlapping four exposure areas, wherein each of the four exposure areas is at or below the maximum reticle field.

5. The device of claim 1, wherein a first pair of the four ICs has a same design, and a second pair of the four ICs has a same design, wherein the design of the first pair is different from the design of the second pair, wherein a first IC of the first pair has a 180 degree orientation relative to a second IC of the first pair, and a third IC of the second pair has a 180 degree orientation relative to a fourth IC of the second pair.

6. The device of claim 5, wherein the design of the first pair is a mirror of the design of the second pair.

7. The device of claim 1, wherein the four ICs have a same design, wherein a first IC of the four ICs has a 90 degree orientation relative to a second IC of the four ICs, a third IC of the four ICs has a 180 degree orientation relative to the second IC of the four ICs, and a fourth IC of the four ICs has a 270 degree orientation relative to the second IC of the four ICs.

8. The device of claim 7, wherein the first and second ICs both have defects, wherein portions of the first and second ICs having the defects are disposed in an unused portion of the device.

9. The device of claim 1, wherein the four ICs have a same design, wherein the four ICs have rotational symmetry such they can be arranged in any orientation on the interposer without changing their function or performance.

10. A method, comprising:
forming an interposer with a horizontal stitch and a vertical stitch using overlapping exposure areas; and
disposing four ICs on the interposer in a 2×2 configuration, wherein each of the four ICs is connected via the interposer to neighboring ICs on two sides.

11. The method of claim 10, wherein a total surface area of the interposer is greater than a maximum reticle field used to form the interposer using the overlapping exposure areas.

12. The method of claim 11, wherein the total surface area of the interposer is at least three times a size of the maximum reticle field.

13. The method of claim 11, wherein the horizontal stitch and the vertical stitch are formed by slightly overlapping four exposure areas, wherein each of the four exposure areas is at or below the maximum reticle field.

14. The method of claim 10, wherein a first pair of the four ICs has a same design, and a second pair of the four ICs has a same design, wherein the design of the first pair is a mirror of the design of the second pair, and wherein a first IC of the first pair has a 180 degree orientation relative to a second IC of the first pair when disposed on the interposer, and a third IC of the second pair has a 180 degree orientation relative to a fourth IC of the second pair when disposed on the interposer.

15. The method of claim 10, wherein the four ICs have a same design, wherein a first IC of the four ICs has a 90 degree orientation relative to a second IC of the four ICs, a third IC of the four ICs has a 180 degree orientation relative to the second IC of the four ICs, and a fourth IC of the four ICs has a 270 degree orientation relative to the second IC of the four ICs.

16. The method of claim 10, wherein the four ICs have a same design, wherein the four ICs have rotational symmetry such they can be arranged in any orientation on the interposer without changing their function or performance.

17. A device, comprising:
four integrated circuits (ICs) arranged in a 2×2 configuration, wherein each of the four ICs is connected to neighboring ICs on at least two sides, and
wherein the four ICs have a same design.

18. The device of claim 17, wherein a first IC of the four ICs has a 90 degree orientation relative to a second IC of the four ICs, a third IC of the four ICs has a 180 degree orientation relative to the second IC of the four ICs, and a fourth IC of the four ICs has a 270 degree orientation relative to the second IC of the four ICs.

19. The device of claim 18, wherein the first and second ICs both have defects, wherein portions of the first and second ICs having the defects are disposed in an unused portion of the device.

20. The device of claim 17, wherein the four ICs have rotational symmetry such they can be arranged in any orientation without changing their function or performance.
